(19) United States
(12) Patent Application Publication
(10) Pub. No.: US 2012/0111402 A1
(43) Pub. Date: May 10, 2012

(54) SOLAR CELL AND SOLAR CELL PRODUCTION METHOD

(75) Inventors: Matthias HOFMANN, Leipzig (DE); Andrey STEKOLNIKOV, Leipzig (DE); Robert SEGUIN, Berlin (DE); Maximilian SCHERFF, Dortmund (DE); Andreas MOHR, Leipzig (DE)

(73) Assignee: Q-CELLS SE, Bitterfeld-Wolfen / OT Thalheim (DE)

(21) Appl. No.: 13/289,151

(22) Filed: Nov. 4, 2011

(30) Foreign Application Priority Data
Nov. 4, 2010 (DE) 10 2010 060 339.2

(51) Int. Cl. H01L 31/0232; H01L 31/18

(52) U.S. Cl. 136/256; 438/69; 257/E31.127

(57) ABSTRACT

A solar cell includes a semiconductor substrate, a rear side passivation layer arranged on a light-remote rear side surface of the substrate, a covering layer arranged on the rear side passivation layer, and a metallization layer arranged on the covering layer. The covering layer has a protective layer section facing the rear side passivation layer and a contact layer section facing the metallization layers. The contact layer section has a higher refractive index than the protective layer section

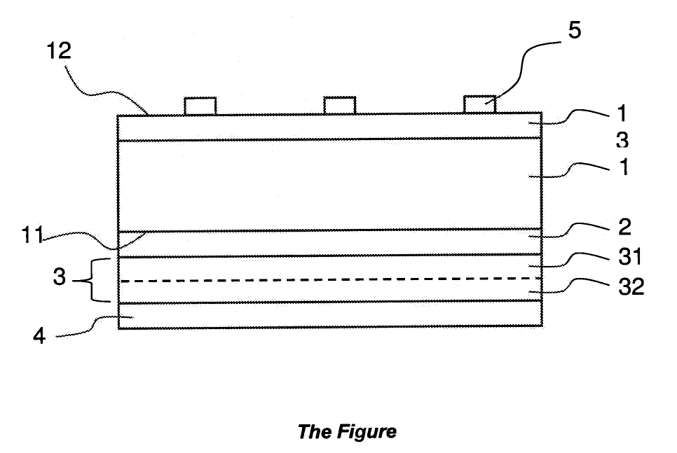

The invention relates to a solar cell and a solar cell production method.

In future solar cells, dielectric passivation layers are expected to be arranged on the rear side surface of their semiconductor substrate in order to minimize charge carrier combinations at the semiconductor surface and thereby to increase the efficiency of the solar cell. A series of materials for passivation layers are known. From the standpoint of the cell, aluminium oxide, in particular, has the greatest potential, since negative charges form at the interface between the semiconductor and the aluminium oxide, which charges bring about a so-called field effect passivation by virtue of the resultant field effect on p-type material.

After passivation, for the purpose of making contact with the solar cell, a metal layer has to be produced onto the passivation layer of the dielectric passivation. In the type of contact-connection for present solar cells that is the most common in industrial production, the metal layer is produced by means of metal pastes that are applied to the semiconductor substrate and subsequently subjected to a thermal treatment. This thermal treatment step is generally known as a firing step.

In this case, for the long-term stability of the solar cell in the finished solar module it is important that the metal paste adheres well to the underlying passivation layer. On the other hand, the reaction that causes the adhesion must not be too aggressive, in order not to damage the passivation. Usually, the adhesion properties of the metal layer and the reaction rate during the firing step are set by means of suitable selection of the proportion of glass frits in the metal paste. However, the reaction rate and reaction depth are also essentially dependent on the type and composition of the material of the passivation layer. In this case, the process window between the case where the metal paste is not aggressive enough, that is to say does not adhere at all, and the case where it is too aggressive, that is to say destroys the passivation, is very narrow. The situation is furthermore aggravated by the fact that the passivation layers have to be very thin with a layer thickness of generally around 100 nanometers. Moreover, the reaction sequence is influenced by inhomogeneities in the dielectric, for example by pinholes, inclusions (blisters), fractures (cracks) or the like, or by transitions between amorphous and crystalline regions.

Consequently, the choice of a suitable combination of passivation layer material and metal paste material always leads to a compromise between passivation properties of the passivation layer and the adhesion effect of the metal layer. Moreover, by way of example, no suitable metal paste material is known which does not attack aluminium oxide passivation layers. Finally, increasing the layer thickness of the passivation layer is not practical economically, since high-quality passivation layers are generally also very expensive.

It is an object of the invention to provide a solar cell and a solar cell production method in which good adhesion between passivation layer and metal layer is obtained in conjunction with a good passivation effect of the passivation layer.

The object is achieved according to the invention by means of a solar cell comprising the features of claim 1 and by means of a solar cell production method comprising the features of claim 15. Advantageous developments of the invention are presented in the dependent claims.

The invention is based on the consideration of separating from one another the effect of the passivation and the adhesion effect of a metallization arranged thereon, in order to avoid the compromise constraint described above. For this purpose, a covering layer is applied to the rear side passivation layer on the rear side, which firstly protects the rear side passivation layer and secondly optimizes the adhesion or the contact between metallization and the semiconductor substrate.

The inventors have discovered that the stability of a layer material with respect to a metal paste during a firing step is dependent on material properties that are directly related to the refractive index. Thereby, the layers having a lower refractive index are more stable with respect to the metal paste, while those having a higher refractive index form a more intimate bond or connection with the metal layer arising therefrom and thus enable better adhesion of the metal layer on the semiconductor substrate. Consequently, the protective layer section of the covering layer, said section facing the rear side passivation layer, can be produced in such a way that it has a low refractive index and thus protects the rear side passivation layer. At the same time, the contact layer section of the covering layer, facing the metallization layer, has a higher refractive index and therefore serves for better adhesion of the metallization layer.

In order to produce a solar cell of this type, after the application, preferably deposition, of a rear side passivation layer onto the semiconductor substrate, a covering layer comprising a protective layer section having a lower refractive index and a contact layer section having a comparatively higher refractive index is applied. Afterwards, the metallization layer is applied, preferably by means of the application of a metal paste, for example an aluminium-containing paste, and a subsequent firing step. Alternatively, the metallization layer can be produced by means of a deposition method such as, for example, by means of physical deposition from the gas phase (physical vapour deposition—PVD) or by means of some other suitable method. The metallization layer is contact-connected to the semiconductor substrate preferably by means of laser-induced contacts (so-called laser fired contacts—LFC), for example distributed in a grid-type fashion of the semiconductor substrate.

After the completion of the solar cell, the covering layer arranged between the rear side passivation layer and the metallization layer thus has a protective layer section facing the rear side passivation layer and a contact layer section facing the metallization layer. Depending on the production method employed, the contact layer section can be obtained partly or completely on the entire rear side surface of the semiconductor substrate. In specific embodiments, however, this contact layer section of the covering layer will combine with the metallization layer or merge in the metal layer in such a way that it is transformed (converted) in terms of its composition partly or (with regard to its thickness) completely.

In any case, however, the covering layer in the finished solar cell will have the contact layer section at least in surface regions, namely for example in the surface regions in which the metallization layer does not cover the covering layer or in which the contact layer section is made thick enough that the reaction between it and the metallization layer does not penetrate completely through the thickness of the contact layer section. This can involve, for example, edge regions of the rear side surface of the semiconductor substrate, for example in the form of a frame around the rear side surface, and/or island regions within the rear side surface of the semiconductor substrate.

In one preferred embodiment it is provided that the covering layer is formed from two or more partial layers, wherein the protective layer section and the contact layer section each are one of the partial layers. In this case, firstly a protective layer is applied as a protective layer section of the covering layer and a contact layer is arranged thereon as a contact layer section of the covering layer. Further intermediate layers can also be formed between the two sections. The embodiment in which the covering layer is formed from partial layers differs from the graded refractive index profile in accordance with the following embodiment in that the covering layer has a rather stepped refractive index profile.

In one advantageous development it is provided that the covering layer has a graded refractive index profile that rises from the protective layer section to the contact layer section. The refractive index profile can rise linearly or non-linearly. For this purpose, it is possible to change the deposition conditions and/or the starting materials during the deposition of the covering layer in a graded fashion or in small steps in order to obtain a corresponding refractive index gradient in the covering layer.

In accordance with one expedient configuration it is provided that the protective layer section and the contact layer section each have a refractive index of between approximately 1.5 and 4.5 in the spectral range that is the operating range of the solar cell. Preferably, the protective layer section has a refractive index of approximately 1.9, while the contact layer section has a refractive index of approximately 2.05. In the case of a graded refractive index profile, the latter preferably varies between 1.9 near the rear side passivation layer and 2.05 near the metallization layer. The refractive index values mentioned here apply to the operating range of the solar cell and can preferably be measured in the optical and/or infrared range of the electromagnetic spectrum, in particular at a wavelength of approximately 630 nanometres.

In specific embodiments it is advantageous if the protective layer section has a refractive index of between approximately 1.7 and 2.4 or 1.8 and 2.1 or 1.85 and 1.95 and the contact layer section has a refractive index of between approximately 1.5 and 4.5 or 1.8 and 2.8 or 3.5 and 4.5. The exact refractive index values can be chosen independently of one another for the protective layer section and the contact layer section, as long as the contact layer section has a higher refractive index than the protective layer section.

It is preferably provided that the protective layer section and the contact layer section are formed from a material compound and the difference in refractive index between the protective layer section and the contact layer section is based on different stoichiometric compositions of the materials in the material compound. This can be achieved during solar cell production by the quantitative ratio of the starting materials being varied during the deposition of the covering layer. By way of example, it is possible to vary the gas flows of the starting materials when employing a plasma-enhanced vapour deposition method (PECVD—Plasma-enhanced chemical vapour deposition) during the deposition of the covering layer in a stepwise manner (in the case of a plurality of partial layers) or in a graded manner (in the case of a graded refractive index profile).

In one expedient embodiment it is provided that the difference in refractive index between the protective layer section and the contact layer section is based on different hydrogen contents in the two sections. In other words, the hydrogen content in the two sections of the covering layer is different. In this case, the protective layer section and the contact layer section are preferably formed from the same material and preferably even with the same stoichiometric composition. Alternatively, however, both the stoichiometric composition and the hydrogen content in the two sections can be set in such a way that the desired refractive indices or the desired refractive index profile form(s).

In one advantageous configuration it is provided that the covering layer is formed from amorphous or microcrystalline silicon, from silicon nitride and/or from silicon oxynitride. In order to vary the refractive index in the case of these materials, it is possible to change in the silicon nitride the ratio between silicon and nitrogen and/or in the silicon oxynitride the ratio between silicon nitride and oxygen in the respective material compounds. To put it another way, it is possible to vary x in SiNx and/or in SiN(1−x)Ox. Besides oxygen, however, other suitable materials can also be incorporated into the silicon nitride in order to control the refractive index, for example carbon.

If the metallization layer is produced by means of metal paste application and a subsequent firing step, metal pastes containing glass fits are generally used. During the firing step, said glass frits react with the layer lying below the metal paste and produce a so-called eutectic layer (for example an Al—Si eutectic when an Al paste is used). Said eutectic layer usually serves both as a passivation layer and as an adhesion layer for the adhesion of the metallization layer to the solar cell.

Particularly when the contact layer section of the covering layer contains silicon, metal pastes containing no glass fits can be used for the rear side metallization. During a subsequent firing step, the metal paste then reacts with the silicon of the contact layer section, such that a eutectic layer is formed here, too. In this process, the silicon is partly or completely converted. In accordance with one preferred configuration, therefore, the protective layer section of the covering layer contains silicon nitride and the contact layer section of the covering layer contains amorphous or microcrystalline silicon.

In accordance with one preferred development it is provided that the rear side passivation layer is formed from aluminium oxide. An aluminium oxide layer of this type, for example in the stoichiometric ratio Al203, is preferably applied by means of atomic layer deposition (ALD), PECVD or PVD. The rear side passivation layer composed of aluminium oxide preferably has a layer thickness of less than 100 nanometres, preferably a layer thickness of approximately 30 nanometres, particularly preferably 10 nanometres.

It is advantageously provided that the rear side passivation layer is formed directly on the semiconductor substrate, the covering layer is formed directly on the rear side passivation layer and/or the metallization layer is formed directly on the covering layer. The direct arrangement means that no further intermediate layer is arranged between the relevant layers. Alternatively, however, for example in a process-dictated fashion, before or during the application of the rear side passivation layer, a thin oxide layer may arise on the semiconductor substrate as an intermediate layer between the semiconductor substrate and the rear side passivation layer.

In accordance with one preferred configuration it is provided that the covering layer substantially covers the entire rear side surface of the semiconductor substrate. In this case, it substantially means that, in a process-dictated fashion, regions of the semiconductor substrate, in particular edge regions, can be present which are not covered by the covering layer. Preferably, the covering layer covers at least 90%, preferably at least 95% or 99%, of the rear side surface of the semiconductor substrate. The features presented in accordance with the embodiment in this paragraph concerning the covering layer are correspondingly also applicable to the protective layer section and the contact layer section, although, as explained above, the contact layer section in specific embodiments can be present merely in surface regions. Said surface regions can comprise, for example, at least approximately 0.5%, 3% or 10% of the rear side surface of the semiconductor substrate.

The surface regions in which the contact layer section is no longer present or is only partly present in its original layer thickness are e.g. the regions in which the metallization layer “eats up” the contact layer during firing. At the cell edges onto which no paste is printed, the complete covering layer is still present even after firing. If the paste is printed very near to the cell edge, this proportion of area becomes very small.

Preferably, a contact-connection on both sides is provided. That means that the solar cell has a metallization both on the light incidence side (front side) and on the light-remote rear side. On the front side, the metallization is preferably realized by means of strip-shaped contact electrodes or by means of a contact grid.

In one expedient development it is provided that the rear side passivation layer and the covering layer together form a reflection layer system for the spectral range that is the operating range of the solar cell. In other words, the optical properties of the rear side passivation layer and of the covering layer are coordinated with one another in such a way that they reflect light penetrating through the semiconductor substrate. As explained above in connection with the refractive index values, the spectral operating range of the solar cell as mentioned here is preferably in the visible and/or infrared range.

The invention is explained below on the basis of exemplary embodiments with reference to a FIGURE. In this case, the single FIGURE shows a solar cell contact-connected on both sides, comprising a rear side passivation layer and a covering layer arranged thereon.

The FIGURE illustrates a solar cell comprising a semiconductor substrate 1. Along a front side surface 12, which faces the incident light during the operation of the solar cell, an emitter layer 13 is formed in the semiconductor substrate 1 by means of doping. If, by way of example, the semiconductor substrate 1 initially comprises an n-type semiconductor, a p-type emitter 13 can be formed by means of doping. The emitter layer 13 is contact-connected by means of front side electrodes 5 arranged thereon.

A rear side passivation layer 2 is arranged on a rear side surface 11 of the semiconductor substrate 1. It serves for passivating the rear side surface 11. A covering layer 3 is arranged on the rear side passivation layer 2, which covering layer simultaneously protects the rear side passivation layer 2 and improves the adhesion of a metallization layer 4 arranged thereon.

For this purpose, the covering layer 3 has a protective layer section 31 facing the rear side passivation layer 2 and a contact layer section 32 facing the metallization layer 4. The protective layer section 31 has a lower refractive index, for example of approximately 1.9. By contrast, the contact layer section 32 has a higher refractive index, for example of approximately 2.05 or 3.5.

In the embodiment illustrated here, the protective layer section 31 and the contact layer section 32 in each form a separate partial layer of the covering layer 3, between which, if appropriate, further intermediate layers (not illustrated in the FIGURE) having refractive index values between those of the two sections 31, 32 can be arranged. Alternatively, the protective layer section 31 and the contact layer section 32 can be sections of a covering layer 3 having a graded refractive index profile. In this case, the graded refractive index profile can rise linearly or in some other suitable manner from the protective layer section 31 towards the contact layer section 32.

### LIST OF REFERENCE SYMBOLS

1 Semiconductor substrate
11 Rear side surface
12 Front side surface
13 Emitter layer
2 Rear side passivation layer
3 Covering layer
31 Protective layer section
32 Contact layer section
4 Metallization layer
5 Front side electrodes

1. Solar cell comprising:
a semiconductor substrate, a rear side passivation layer arranged on a light-remote rear side surface of the semiconductor substrate,
a covering layer arranged on the rear side passivation layer, and
a metallization layer arranged on the covering layer wherein the covering layer has a protective layer section facing the rear side passivation layer and, at least in surface regions, a contact layer section facing the metallization layer, wherein the contact layer section has a higher refractive index than the protective layer section.

2. Solar cell according to claim 1, wherein the covering layer is formed from two or more partial layers, wherein the protective layer section and the contact layer section each are one of the partial layers.

3. Solar cell according to claim 1, wherein the covering layer has a graded refractive index profile that rises from the protective layer section to the contact layer section.

4. Solar cell according to claim 1 wherein the protective layer section and the contact layer section each have a refractive index of between approximately 1.5 and 4.5 in the spectral range that is the operating range of the solar cell.

5. Solar cell according to claim 4, wherein the protective layer section has a refractive index of between approximately 1.7 and 2.4 or 1.8 and 2.1 or 1.85 and 1.95, and the contact layer section has a refractive index of between approximately 1.5 and 4.5 or 1.8 and 2.8 or 3.5 and 4.

6. Solar cell according to claim 1 wherein the protective layer section and the contact layer section are formed from a material compound and the difference in refractive index between the protective layer section and the contact layer section is based on different stoichiometric compositions of the materials in the material compound.

7. Solar cell according to claim 1 wherein the difference in refractive index between the protective layer section and the contact layer section is based on different hydrogen contents in the two sections.

8. Solar cell according to claim 1 wherein the covering layer is formed from amorphous or microcrystalline silicon, from silicon nitride and/or from silicon oxynitride.

9. Solar cell according to claim 1 wherein the protective layer section of the covering layer contains silicon nitride and/or the contact layer section of the covering layer contains amorphous or microcrystalline silicon.

10. Solar cell according to claim 1 wherein the rear side passivation layer is formed from aluminium oxide, amorphous silicon, amorphous silicon nitride or amorphous silicon oxide.

11. Solar cell according to claim 1 wherein the rear side passivation layer is formed directly on the semiconductor substrate, the covering layer is formed directly on the rear side passivation layer and/or the metallization layer is formed directly on the covering layer.

12. Solar cell according to claim 1 wherein the covering layer substantially covers the entire rear side surface of the semiconductor substrate

13. Claim 1 further comprising a contact-connection on both sides.

14. Solar cell according to claim 1 wherein the rear side passivation layer and the covering layer together form a reflection layer system for the spectral range that is the operating range of the solar cell.

15. Solar cell production method comprising the following steps:
providing a semiconductor substrate;
applying a rear side passivation layer to a light-remote rear side surface of the semiconductor substrate;
applying a covering layer to the rear side passivation layer; and
applying a metallization layer to the covering layer,
wherein the covering layer is applied with a protective layer section facing the rear side passivation layer and a contact layer section facing the metallization layer in such a way that the contact layer section has a higher refractive index than the protective layer section.
